(19) United States
(12) Patent Application Publication
(10) Pub. No.: US 2026/0324438 A1
(43) Pub. Date: Oct. 15, 2026

(54) ELECTROSTATIC DISCHARGE PROTECTION DEVICE

(71) Applicant: STMICROELECTRONICS INTERNATIONAL N.V., Geneva (CH)

(72) Inventors: Aurelie ARNAUD, Saint-Cyr-sur-Loire (FR); Irene Monica Lasar SAVARI MUTHU, Singapore (SG)

(21) Appl. No.: 19/630,684

(22) Filed: Mar. 27, 2026

(30) Foreign Application Priority Data
Apr. 9, 2025 (FR) 2503753

(51) Int. Cl. H10W 42/60; H10D 8/00; H10D 8/01; H10D 62/834; H10D 80/20

(52) U.S. Cl. CPC H10W 42/60; H10D 8/045; H10D 8/411; H10D 62/834; H10D 80/231

(57) ABSTRACT

The present disclosure provides an electrostatic discharge protection device. An example electrostatic discharge protection device consecutively with: a semiconductor substrate doped of P-type; a first semiconductor layer doped of N-type, on and in contact with a top face of the semiconductor substrate; a second semiconductor layer doped with boron atoms, on and in contact with the first semiconductor layer, the second semiconductor layer having a concentration of boron atoms greater than or equal to 10¹⁷ atoms/cm³; and a third semiconductor layer doped of N-type, on a top face of the second semiconductor layer, the first semiconductor layer being more heavily doped than the third semiconductor layer, the device further including isolation trenches extending through the first, second, and third semiconductor layers, and opening into the semiconductor substrate, defining, in the third semiconductor layer, between the isolation trenches, at least one well.

### CROSS REFERENCE TO RELATED APPLICATION(S)

This application claims the priority benefit of French Patent Application Number 2503753, filed on Apr. 9, 2025, entitled “DISPOSITIF DE PROTECTION CONTRE LES DÉCHARGES ÉLECTROSTATIQUES” which is hereby incorporated by reference to the maximum extent allowable by law.

### Technical Field

The present disclosure generally relates to electronic devices, and more particularly to electrostatic discharge or ESD protection electronic devices.

### Background

Various electrostatic discharge prevention and protection devices are known.

It would be desirable to at least partially overcome some of the drawbacks of known embodiments of such devices.

### Brief Summary

To this end, one embodiment provides an electrostatic discharge protection device consecutively comprising:
a semiconductor substrate doped of P-type;
a first semiconductor layer doped of N-type, on and in contact with a top face of the semiconductor substrate;
a second semiconductor layer doped with boron atoms, on and in contact with the first semiconductor layer, the second semiconductor layer having a concentration of boron atoms greater than or equal to 1017 atoms/cm3; and
a third semiconductor layer doped of N-type, on a top face of the second semiconductor layer, the first semiconductor layer being more heavily doped than the third semiconductor layer, the device further including isolation trenches extending through the first, second, and third semiconductor layers, and opening into the semiconductor substrate, defining, in the third semiconductor layer, between the isolation trenches, at least one well.

According to an embodiment, the second semiconductor layer has a thickness in the range from 3 µm to 5 µm.

According to an embodiment, the insulation trenches are filled with an insulating material.

According to an embodiment, the second semiconductor layer has a boron concentration in the range from 1017 atoms/cm3 to 10¹⁹ atoms/cm³.

According to an embodiment, the first semiconductor layer has a concentration of N-type doping elements in the range from 1016 atoms/cm3 to 10¹⁸ atoms/cm³.

According to an embodiment, the first semiconductor layer has a thickness in the range from 1 µm to 5 µm.

According to an embodiment, said at least one well has a width in the range from 50 µm to 150 µm.

According to an embodiment, said at least one well comprises a diode.

According to an embodiment, the insulating trenches define in the third layer several consecutive wells each comprising a diode, the diodes of said successive wells being connected in series.

According to an embodiment, the first and second layers each extend continuously over substantially the whole surface of the substrate, and are interrupted only by the insulation trenches.

According to an embodiment, the first and second layers are interrupted between two adjacent insulation trenches.

Another embodiment provides a method for manufacturing an electrostatic discharge protection device comprising the following consecutive steps:
a) forming a first semiconductor layer doped of N-type, on and in contact with a top face of a semiconductor substrate doped of P-type;
b) forming a second semiconductor layer doped with boron atoms, on and in contact with the first semiconductor layer, the second semiconductor layer having a concentration of boron atoms greater than or equal to 1017 atoms/cm3;
c) forming a third semiconductor layer doped of N-type on a top face of the second semiconductor layer, the first semiconductor layer being more heavily doped than the third semiconductor layer; and
d) forming two isolation trenches extending through the first, second, and third semiconductor layers, and opening into the semiconductor substrate, defining, in the third semiconductor layer, between the isolation trenches, a well.

According to an embodiment, the first layer is epitaxially grown from the top face of the substrate, and the second layer is formed by implantation of boron atoms from the top face of the first layer.

According to an embodiment, the first layer and the second layer are respectively formed by implantation of N-type doping elements and by implantation of boron atoms from the top face of the semiconductor substrate.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A and FIG. 1B are schematic and partial views of examples of electrostatic discharge protection electronic devices;

FIG. 2 is a schematic and partial view of an example of an electrostatic discharge protection electronic device according to a first embodiment;

FIG. 3 is a schematic and partial view of an example of an electrostatic discharge protection electronic device according to a second embodiment;

FIG. 4A, FIG. 4B, FIG. 4C, and FIG. 4D are schematic and partial views of successive steps in an example of a method for manufacturing the electronic device illustrated in FIG. 3; and

FIG. 5 is a circuit diagram of the electrostatic discharge protection circuit of the electronic device illustrated in FIG. 3.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms "front", "back", "top", "bottom", "left", "right", etc., or to relative positional qualifiers, such as the terms "above", "below", "higher", "lower", etc., or to qualifiers of orientation, such as "horizontal", "vertical", etc., reference is made to the orientation shown in the figures.

Unless specified otherwise, the expressions "around", "approximately", “substantially” and "in the order of" signify within 10 % or 10°, and preferably within 5 % or 5°.

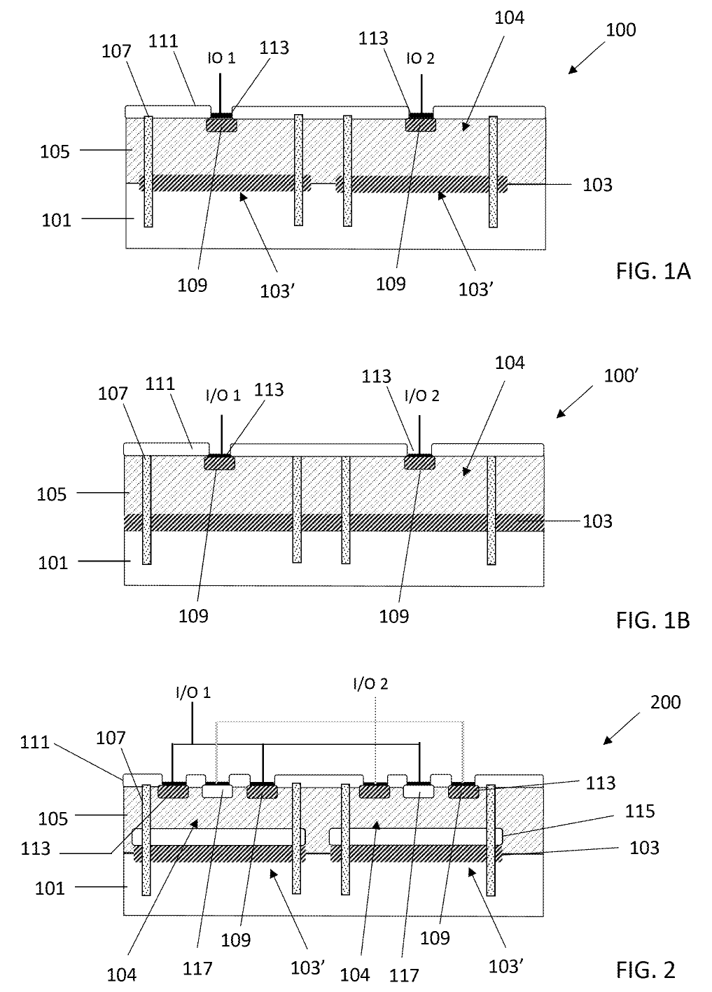

FIG. 1A and FIG. 1B are schematic and partial views of examples of electrostatic discharge protection electronic devices. More specifically, FIG. 1A illustrates an electronic device 100, and FIG. 1B illustrates an electronic device 100'.

Device 100 comprises a semiconductor substrate 101 doped of P-type. By way of example, substrate 101 is doped with boron atoms. By way of example, semiconductor substrate 101 is made of a high-resistivity material, for example with a resistivity greater than 80 Ω.cm. By way of example, the substrate 101 has a concentration of doping elements in the range from 10¹³ atoms/cm³ to 10¹⁵ atoms/cm³, e.g. of the order of 10¹⁴ atoms/cm³.

Device 100 comprises a semiconductor layer 103, arranged in and on substrate 101 and, for example, in contact with the top face of substrate 101. For example, in device 100, layer 103 extends over the substrate 101 over the top surface of the substrate 101. In device 100, layer 103 does not extend over the whole top face of substrate 101. More particularly, in FIG. 1A, layer 103 comprises a plurality of portions 103' extending over the surface of substrate 101. By way of example, the portions 103' of layer 103 are, in FIG. 1A, dissociated from each other. Layer 103 is N-type doped. By way of example, layer 103 is doped with phosphorus or arsenic atoms. Layer 103 has, for example, a concentration of doping elements in the range from 10¹⁶ atoms/cm³ to 10¹⁸ atoms/cm³, e.g. of the order of 10¹⁷ atoms/cm³. Layer 103, for example, has a thickness in the range from 1 µm to 5 µm. By way of example, layer 103 has a thickness of the order of 2 µm when doped with arsenic atoms. By way of example, layer 103 has a thickness of the order of 4 µm when doped with phosphorus atoms.

The device 100 comprises a further semiconductor layer 105, arranged on the top face of layer 103 and, for example, in contact with layer 103. For example, layer 105 extends between portions 103' of layer 103 and is there, for example, in contact with the substrate 101. Layer 105 is N-type doped. Layer 103 is more heavily doped than layer 105. For example, layer 105 has a concentration of doping elements in the range from 10¹³ atoms/cm³ to 10¹⁵ atoms/cm³, e.g. in the order of 6.10¹³ atoms/cm³. By way of example, layer 105 has a thickness in the range from 10 µm to 14 µm, for example of the order of 12 µm.

The device includes insulating trenches 107 extending through the semiconductor layer 105 and the semiconductor layer 103, and opening into the substrate 101. The trenches 107 serve to electrically isolate various components of the protection device from each other.

By way of example, the trenches 107 extend deeper than the top face of the substrate 101. By way of example, in FIG. 1A, two trenches 107 pass through each portion 103' of layer 103. The trenches thus delimit wells 104 in layer 105. By way of example, each well 104 is thus delimited on its bottom face by the layer 103. Further, each well 104 is delimited on its flanks by trenches 107. By way of example, each well 104 houses an electronic component.

By way of example, trenches 107 are filled with an electrically insulating material. By way of example, trenches 107 are filled with an oxide, such as silicon oxide, thermal oxide, undoped silicate glass (USG) or tetraethyl orthosilicate (TEOS).

By way of example, each well 104 has a width in the range from 50 µm to 150 µm, for example in the range from 80 µm to 120 µm, e.g. of the order of 100 µm.

By way of example, each portion 103' of the layer 103 is wider than the width of a well 104. For example, each portion 103' thus extends beyond the opposite side of the well 104, on either side of the well 104. Each portion 103' extends laterally, for example, beyond the two trenches 107 that pass through it.

By way of example, device 100 comprises a region 109 formed in layer 105. For example, region 109 is flush with the top surface of layer 105. For example, region 109 is N-type doped. By way of example, region 109 is more heavily doped than layer 105. For example, region 109 has a concentration of doping elements in the range from 10¹⁸ atoms/cm³ to 10²⁰ atoms/cm³, for example of the order of 10¹⁹ atoms/cm³. By way of example, region 109 extends from the top face of layer 105 into layer 105 to a depth in the range from 1 µm to 5 µm.

By way of example, an insulating layer 111 covers the top surface of layer 105. By way of example, layer 111 covers the whole layer 105 without covering regions 109. In other words, layer 111 covers the whole top face of layer 105 while being open opposite regions 109. Layer 111 is for example made of an electrically insulating material.

By way of example, layer 111 is made of an oxide, such as silicon oxide, thermal oxide, undoped silicate glass (USG) or tetraethyl orthosilicate (TEOS).

By way of example, each region 109 is covered by and in contact with a contact metallization 113. Each contact metallization is, for example, connected to a terminal I/O of a circuit to be protected against electrostatic discharge. For example, one region 109 is thus connected to a terminal IO1. Another adjacent region 109 is, for example, connected to a terminal IO2.

The device 100’ illustrated in FIG. 1B is identical to the device 100 illustrated in FIG. 1A, except that in the device 100’, the semiconductor layer 103 extends over the whole surface of the device 100’. More precisely, in this example, layer 103 extends over the whole top face of substrate 101. In this example, layer 103 extends then under a plurality of wells 104.

In this example, layer 105 covers the whole top face of layer 103, and is, for example, in contact with layer 103. In this example, layer 105 is thus not in contact with substrate 101.

The inventors have found that, in structures of the type described in relation to FIGS. 1A and 1B, positive electrical charges trapped at the interface between the oxide of trenches 107 and silicon lead to an accumulation of negative charges, in substrate 101, under layer 103, at the interface between trenches 107 and silicon, to compensate for the positive charges of substrate 101. Negative charges accumulated along the trenches 107 below the layer 103 can cause a conduction channel to be created in the substrate 101, degrading the electrical performance of the device.

FIG. 2 is a schematic and partial view of an example of an electrostatic discharge protection electronic device 200 according to a first embodiment.

The device 200 illustrated in FIG. 2 is, for example, similar to the device 100 illustrated in FIG. 1A, except that the device 200 comprises a boron-doped silicon layer 115 on and in contact with layer 103. In this embodiment, layer 115 is in contact, via its bottom face, with the top face of layer 103. In this embodiment, layer 115 is in contact, via its top face, with the bottom face of layer 105. By way of example, in this embodiment, layer 115 extends over the whole portions of layer 103. By way of example, in this embodiment, layer 115 extends only opposite portions 103' of layer 103.

Layer 115 has a boron atom concentration greater than or equal to 10¹⁷ atoms/cm3, for example in the range from 10¹⁷ atoms/cm3 to 10¹⁹ atoms/cm3, e.g. of the order of 2.10¹⁸ atoms/cm3. In this embodiment, layer 115 has a thickness in the range 3 µm to 5 µm, for example of the order of 4 µm.

In the example illustrated in FIG. 2, the device 200 comprises two regions 109. By way of example, device 200 comprises in addition a region 117 formed in layer 105. For example, region 117 is flush with the top surface of layer 105. For example, regions 109 are formed on either side of region 117. Further, like region 109, region 117 is topped by a contact metallization 113. For example, the contact metallization 113 is in contact with region 117. By way of example, region 117 is P-type doped. For example, region 117 has a doping level in the range from 10¹⁸ atoms/cm³ to 10²⁰ atoms/cm³, e.g. of the order of 10¹⁹ atoms/cm³. By way of example, region 117 extends from the top face of layer 105 into layer 105 to a depth in the range from 1 µm to 5 µm.

For example, in the device shown in FIG. 2, the two-contact metallizations 113 formed opposite the regions 109 of the well 104 located on the left side of FIG. 2 are, for example, electrically connected to the contact metallizations 113 formed opposite the region 117 of the well 104 located on the right side of FIG. 2. In addition, these metallizations are connected to an I/O terminal 1 of a circuit to be protected.

For example, in the device shown in FIG. 2, the two-contact metallizations 113 formed opposite the regions 109 of the well 104 located on the right side of FIG. 2 are, for example, electrically connected to the contact metallizations 113 formed opposite the region 117 of the well 104 located on the left side of FIG. 2. In addition, these metallizations are connected to an I/O 2 terminal of a circuit to be protected.

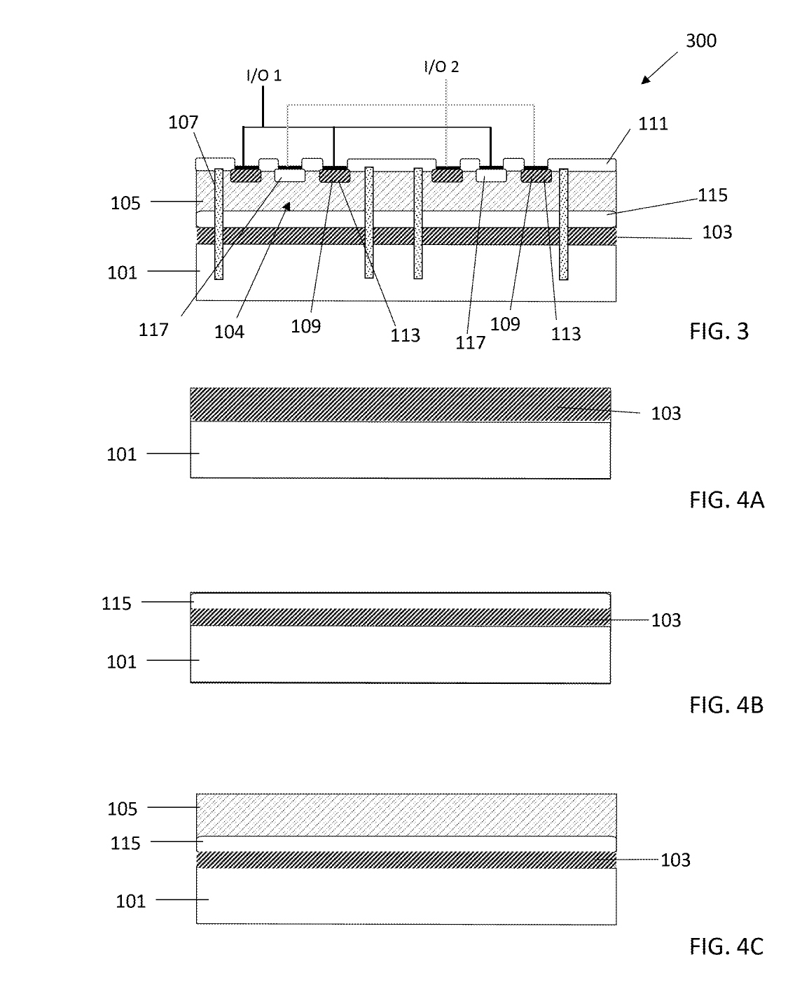

FIG. 3 is a schematic and partial view of an example of an electrostatic discharge protection electronic device 300 according to a second embodiment.

The device 300 illustrated in FIG. 3 is identical to the device 200 illustrated in FIG. 2, except that in device 300, semiconductor layer 103 and layer 115 extend over the whole surface of device 300. More precisely, in this example, layers 103 and 115 extend over the whole top face of substrate 101. In this example, layers 103 and 115 extend under a plurality of wells 104.

In this example, layer 105 covers thus the whole top surface of layer 103, and is for example in contact with layer 103. In this example, layer 105 is thus not in contact with substrate 101.

One advantage of the embodiments described in FIGS. 2 and 3 is that they make it possible to limit the conduction currents forming around the trenches 107 under layer 103, due to the addition of a further PN junction formed at the interface between layers 115 and 103.

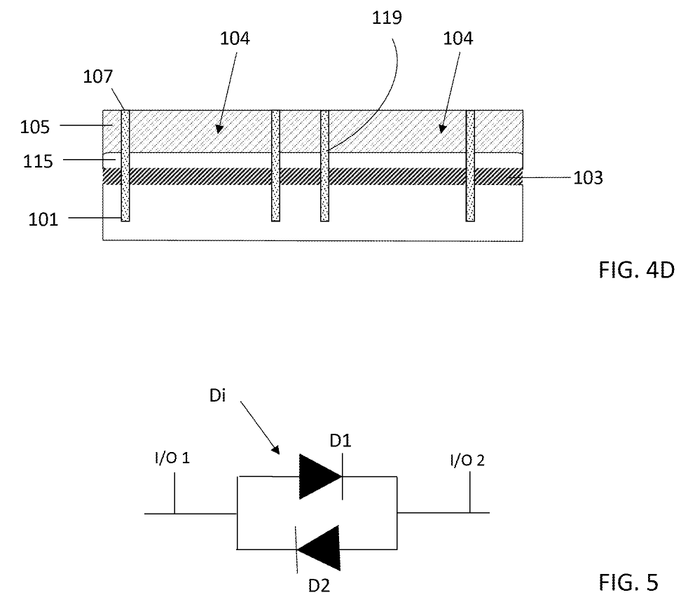

FIG. 4A, FIG. 4B, FIG. 4C, and FIG. 4D are schematic and partial views of successive steps in an example of a method for manufacturing the electronic device 300 illustrated in FIG. 3.

FIG. 4A illustrates a structure including layer 103 and substrate 101.

Such a structure can be performed according to two different implementation modes.

In a first implementation mode, such a structure is made from the substrate 101 on which the layer 103 is formed. By way of example, layer 103 is epitaxially grown from the top face of substrate 101. For example, layer 103 is doped in-situ during epitaxial growth.

In a second implementation mode, such a structure is formed by forming the layer 103, by implanting or diffusing doping elements, in a top part of the substrate 101. For example, implanting doping elements is performed from the top face of substrate 101. For example, the layer 103 is formed in the substrate 101 so that the layer 103 is flush with the top face of the substrate 101. By way of example, in this step, implantation is performed over the whole surface of semiconductor substrate 101.

FIG. 4B illustrates a structure obtained at the end of a step for forming layer 115 on the top face of the structure illustrated in FIG. 4A.

During this step, layer 115 is formed, for example, by implanting or diffusing doping elements into a top part of layer 103. Implanting doping elements is, for example, performed from the top face of layer 103. For example, layer 115 is formed in layer 103 so that layer 115 is flush with the top face of layer 103. By way of example, during this step, Implanting is performed over the whole surface of layer 103. During this step, the doping elements forming layer 115 are implanted less deeply than the doping elements forming layer 103.

FIG. 4C illustrates a structure obtained at the end of a step for forming layer 105 on the top face of the structure illustrated in FIG. 4B.

By way of example, layer 105 is formed on and in contact with layer 115.

For example, layer 105 is epitaxially grown. For example, layer 105 is doped in-situ during epitaxial growth.

The steps for epitaxying and doping allowing layer 105 to be formed are performed, for example, from the top face of the structure in the orientation shown in FIG. 4B.

For example, after this step, layers 115 and 103 may diffuse into layer 105. Such diffusion may, for example, lead to a reduction in the thickness of layer 105 in favor of layers 103 and 115.

FIG. 4D illustrates a structure obtained at the end of a step for forming insulation trenches 107 in the structure illustrated in FIG. 4C.

For example, forming trenches 107 comprises, in a first stage, forming openings 119 in layers 105, 115 and 103. By way of example, the openings pass through the whole layers 105, 115, and 103. By way of example, the openings 119 are non-through, for example. The openings 119 extend, for example, from the top face of layer 115, and open into the substrate 101.

Forming trenches 107 further includes, for example, in a second stage, filling the openings 119 with insulating material. During the filling step, the insulating material deposited in excess covers all or part of the top face of layer 105. This step is followed, for example, by a step for removing the excess insulating material covering the top face of layer 105. The removal step is performed, for example, by mechanical or mechanochemical polishing.

At the end of this step, the structure undergoes, for example, a step for implanting regions 109 and 117. By way of example, regions 117 are formed independently of regions 109.

The structure further undergoes, for example, a step for forming the insulating layer 111 on the top face of the layer 105. By way of example, at the end of its deposition, the layer 111 is for example etched so as to reveal the top face of regions 109 and 117.

Alternatively, regions 109 and 117 are formed prior forming trenches 107. By way of example, filling the trenches 107 and forming layer 111 correspond to one and the same step. In this alternative, depositing the insulating material filling the openings 119 goes on while the openings 119 are completely filled. This material is thus deposited on the top face of layer 105. In contrast to what has been described above in relation to the formation of trenches 107, this layer is retained, for example, so as to form layer 111.

Again, at the end of these steps, contact metallization 113 are formed, for example, on and in contact with regions 109 and 117.

The steps described above correspond to an example of a method for manufacturing the electronic device 300 illustrated in FIG. 3. The method for manufacturing the device 200 illustrated in FIG. 2 may be very similar to that described above, except that layers 103 and 115 are both formed by locally implanting doping elements through a mask. By way of example, the two steps for implanting doping elements allowing layers 103 and 115 to be formed are performed through a one and the same mask.

FIG. 5 is a circuit diagram illustrating the electrostatic discharge protection circuit of the electronic device 300 illustrated in FIG. 3.

The electrical diagram equivalent to the electronic device 300 illustrated in FIG. 3 corresponds to Di diodes connected in direct series, which can be connected in series depending on the number of well 104.

For example, in the well 104 on the right of FIG. 2, region 117 corresponds to an anode of a first diode D1 and regions 109 correspond to a cathode of diode D1.

For example, in the well 104 located on the left side of FIG. 2, region 117 corresponds to an anode of a second diode D2 and regions 109 correspond to a cathode of diode D2.

In the circuit diagram of FIG. 5, the cathode of diode D1 is connected, for example, to the anode of diode D2, these two terminals being connected, for example, to the I/O 2 terminal of a circuit to be protected. In the circuit diagram shown in FIG. 5, the cathode of diode D2 is connected, for example, to the anode of diode D1, these two terminals being connected, for example, to the I/O 1 terminal of a circuit to be protected.

For example, one can provide that the diodes D1, D2 of the electronic device 300 may be reverse-biased diodes. In this example, the electronic device 300 comprises in each of the wells 104, a buried region under and around the region 117. For example, such a buried region is P-type doped, for example, less heavily than region 117.

One advantage of the present embodiments is that they allow mutually isolated wells 104 to be created, and thus laterally conductive components to be formed in the different wells.

Numerous applications are likely to benefit from the advantages offered by electronic devices 200 and 300, and these devices 200 and 300 can be integrated into various types of component.

By way of example, devices 200 and 300 can be integrated into a component intended to be used in personal electronics, for example in order to increase the volume of information exchanged by RF communication, in 5G communication systems, or more generally in any connected component. The component is, for example, a cell phone, or smartphone, or part of an Internet of Things network. The component is for example connected by 5G, WiFi or broadband communication. For example, the component comprises high-rate interfaces, for example with advanced filtering and electrostatic discharge protection.

Various embodiments and variants have been described. Those skilled in the art will understand that certain features of these embodiments can be combined and other variants will readily occur to those skilled in the art.

In addition, one can provide that the wells accommodate other types of components, for example other types of two-legged components.

Finally, the practical implementation of the embodiments and variants described herein is within the capabilities of those skilled in the art based on the functional description provided hereinabove.

1. An electrostatic discharge protection device, consecutively comprising:
a semiconductor substrate doped of P-type;
a first semiconductor layer doped of N-type, on and in contact with a top face of the semiconductor substrate;
a second semiconductor layer doped with boron atoms, on and in contact with the first semiconductor layer, the second semiconductor layer having a concentration of boron atoms greater than or equal to 10¹⁷ atoms/cm³; and
a third semiconductor layer doped of N-type, on a top face of the second semiconductor layer, the first semiconductor layer being more heavily doped than the third semiconductor layer,
wherein the electrostatic discharge protection device further including insulation trenches extending through the first semiconductor layer, the second semiconductor layer, and
wherein the third semiconductor layer, and opening into the semiconductor substrate, defining, in the third semiconductor layer, between the insulation trenches, at least one well.

2. The electrostatic discharge protection device according to claim 1, wherein the second semiconductor layer has a thickness in a range from 3 µm to 5 µm.

3. The electrostatic discharge protection device according to claim 1, wherein the insulation trenches are filled with an insulating material.

4. The electrostatic discharge protection device according to claim 1, wherein the second semiconductor layer has a boron concentration in a range from 10¹⁷ atoms/cm³ to 10¹⁹ atoms/cm³.

5. The electrostatic discharge protection device according to claim 1, wherein the first semiconductor layer has a concentration of N-type doping elements in a range from 10¹⁶ atoms/cm³ to 10¹⁸ atoms/cm³.

6. The electrostatic discharge protection device according to claim 1, wherein the first semiconductor layer has a thickness in a range from 1 µm to 5 µm.

7. The electrostatic discharge protection device according to claim 1, wherein the at least one well has a width in a range from 50 µm to 150 µm.

8. The electrostatic discharge protection device according to claim 1, wherein the at least one well comprises a diode.

9. The electrostatic discharge protection device according to claim 1, wherein the insulation trenches define, in the third semiconductor layer, several consecutive wells each comprising a diode, the diodes of successive of the several consecutive wells being connected in series.

10. The electrostatic discharge protection device according to claim 1, wherein the first semiconductor layer and the second semiconductor layer each extend continuously over substantially a whole surface of the semiconductor substrate, and are interrupted only by the insulation trenches.

11. The electrostatic discharge protection device according to claim 1, wherein the first semiconductor layer and second semiconductor layer are interrupted between two adjacent insulation trenches.

12. A method for manufacturing an electrostatic discharge protection device, comprising the following consecutive steps:
a) forming a first semiconductor layer doped of N-type, on and in contact with a top face of a semiconductor substrate doped of P-type;
b) forming a second semiconductor layer doped with boron atoms, on and in contact with the first semiconductor layer, the second semiconductor layer having a concentration of boron atoms greater than or equal to 10¹⁷ atoms/cm³;
c) forming a third semiconductor layer doped of N-type on a top face of the second semiconductor layer, the first semiconductor layer being more heavily doped than the third semiconductor layer; and
d) forming two insulation trenches extending through the first semiconductor layer, the second semiconductor layer, and the third semiconductor layer, and opening into the semiconductor substrate, defining, in the third semiconductor layer, between the two insulation trenches, a well.

13. The method according to claim 12, wherein the first semiconductor layer is epitaxially grown from the top face of the semiconductor substrate, and the second semiconductor layer is formed by implantation of boron atoms from the top face of the first semiconductor layer.

14. The method according to claim 12, wherein the first semiconductor layer and the second semiconductor layer are respectively formed by implantation of N-type doping
elements and by implantation of boron atoms from the top face of the semiconductor substrate.
